(19) United States
(12) Patent Application Publication
(10) Pub. No.: US 2008/0072204 A1
(43) Pub. Date: Mar. 20, 2008

(54) Layout design of multilayer printed circuit board

(75) Inventor: Yen-Hao Chen, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 11/523,073

(22) Filed: Sep. 19, 2006

(51) Int. Cl. G06F 17/50; H03K 17/693

(52) U.S. Cl. 716/15

(57) ABSTRACT

A layout design of a multilayer printed circuit board (PCB) is provided, which makes use of partial electromagnetic band gap (EBG) structure to constitute a power layer or a ground layer. The EBG structure is mainly used on the linear transmission path from the port of the first integrated circuit to the port of the second integrated circuit on the power layer or the ground layer, so as to overcome the problems concerning self-impedance and transfer-impedance easily occurred in the conventional complete EBG structure.

### BACKGROUND OF THE INVENTION

1. Field of Invention

The present invention relates to a multilayer printed circuit board (PCB), and more particular, to a multilayer PCB having an electromagnetic band gap (EBG) structure formed only on the linear transmission path between ports of integrated circuits (IC).

2. Related Art

In the design of high-frequency digital circuits, the trend is toward high speed, small volume, low voltage, and so on. Particularly, under the circumstance that the speed of central processing units (CPU) in personal computer systems has been increasingly improved, the effect of ground bounce noise (GBN) on systems becomes aggravated, so that it is important and necessary to reduce the GBN effect.

The GBN mainly results from high-speed digital circuits, in which the discontinuity of signal line and the parasitic inductance effect of power layer/ground layer cause a transient voltage ΔV in the power layer during the quick switching of an integrated circuit (IC), and the noise is referred to as the ground bounce noise (GBN). The faster the speed of the system is, or the more pins the integrated circuit for simultaneously converting logic states has, the more easily the phenomenon of GBN is generated from a stray inductance caused by the layout design of the circuit path or the packaging of the integrated circuit, and the GBN is one of the main reasons causing noises of the digital system. Commonly, the phenomenon resulting from the GBN incurs an error action in logic operation of the system. Regarding the power layer as a parallel waveguide structure, the GBN causes the resonance of the power layer. And it is found that the effect of the GBN on the signal integrity and electromagnetic interference (EMI) is significant near the resonance frequency point.

The prior art has proposed a method of reducing the GBN effect in the multilayer PCB, which involves connecting a large decoupling capacitor near a surge source. Please refer to FIG. 1 of a schematic view of the decoupling capacitor disposed on a multilayer PCB according to the prior art. As shown in FIG. 1, on a multi-layered PCB 101, a decoupling capacitor 105 is connected to an integrated circuit 104 and is then connected between a power layer 1011 and a ground layer 1012, or a plurality of decoupling capacitors is added around the noise source to form the capacitor wall to provide protection, and a rectangular slit is formed in the power layer to provide an isolation effect, and so on. However, these methods still have shortcomings in reducing the GBN effect.

As the trend of the design of digital circuits is toward higher speed and higher frequency, it has been proposed to use the EBG structure to reduce the GBN of the power plane or the ground plane in the high frequency band. The current methods all use a complete EBG structure in the entire power layer or ground layer. Please refer to FIG. 2 of a schematic view of the power layer with the EBG structure in the multilayer PCB according to the prior art. As shown in FIG. 2, the entire power layer 2011 or ground layer 2012 on the multilayer PCB 201 is of the EBG structure, and has the disadvantages that the self-impedance thereof is apparently larger than that of the power layer or the ground layer without the EBG structure, and the transfer-impedance thereof is larger than that of the power layer or the ground layer without the EBG structure at a frequency below several hundreds of MHz.

### SUMMARY OF THE INVENTION

In order to solve the aforementioned problems, the present invention discloses a layout design of a multilayer PCB, which does not only make use of the EBG structure to constitute the power layer or the ground layer to achieve the purpose of reducing the self-impedance and transfer-impedance of the multilayer PCB.

The technical scheme of the present invention uses the EBG structure on the transmission path from the port of the first integrated circuit to the port of the second integrate circuit on the power layer or the ground layer, and the remaining region of the power layer or the ground layer is a plane without the EBG structure. Here, the surface area increases as compared with the power layer or the ground layer which uses the EBG structure only.

According to the technical scheme of the present invention, at a frequency above 500 MHz, the improving performance of reducing the transfer-impedance is almost the same as the prior art using the EBG structure only. However, as far as the improving performance of the self-impedance is concerned, at the same frequency, the present invention can acquire a stable self-impedance as compared with the conventional art using the EBG structure only and without using the EBG structure.

The above description of the present invention and the following illustration of the present invention are intended to explain the spirit and principles of the present invention, and the scope of the present invention is defined by the claims of the present invention.

Further scope of applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is the schematic view of the decoupling capacitor disposed on the conventional multilayer PCB.

FIG. 2 is the schematic view of the power layer with the EBG structure in the conventional multilayer PCB.

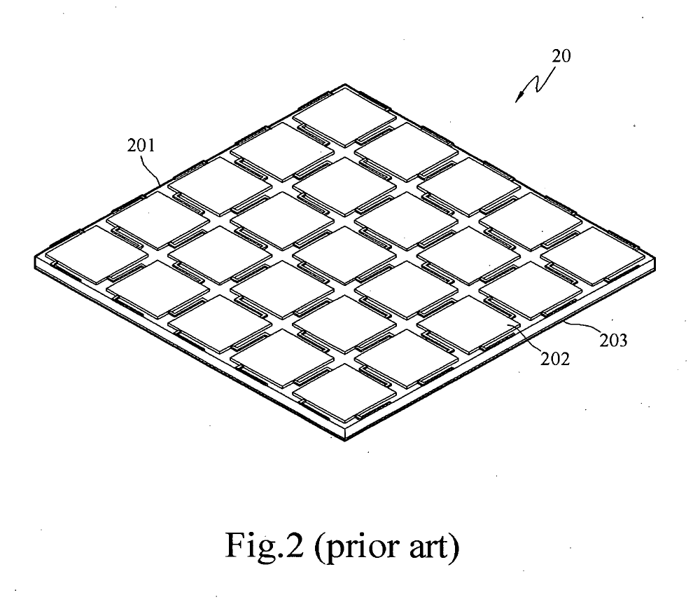

FIG. 3 is the schematic view of the EBG structure according to the present invention.

FIG. 4 is the diagram of transfer-impedance curve after using the EBG structure plane according to the present invention.

FIG. 5 is the diagram of self-impedance curve after using the EBG structure plane according to the present invention.

### DETAILED DESCRIPTION OF THE INVENTION

The detailed features and advantages of the present invention will be described fully in the following part, whose contents will be sufficient to make those skilled in the art appreciate the technological contents of the present invention and implement it thereby, and those skilled in the art can easily appreciate the related objectives and advantages of the present invention according to the contents, claims, and drawings disclosed in the present specification.

The present invention includes changing the area of the EBG structure of the power layer or the ground layer to reduce the self-impedance and transfer-impedance of the multilayer PCB.

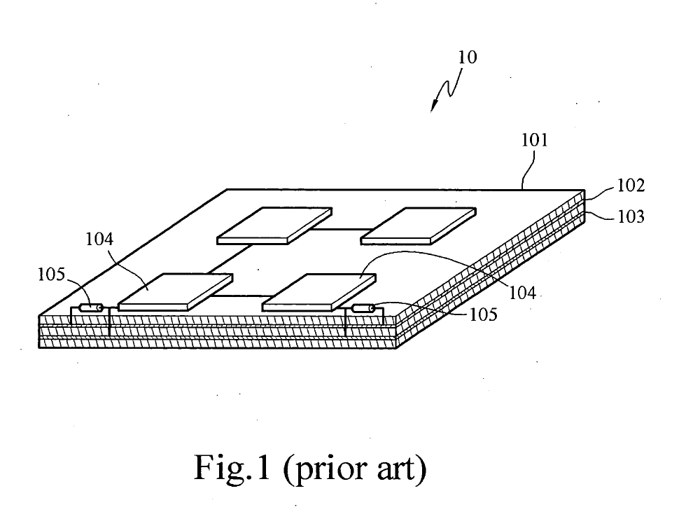

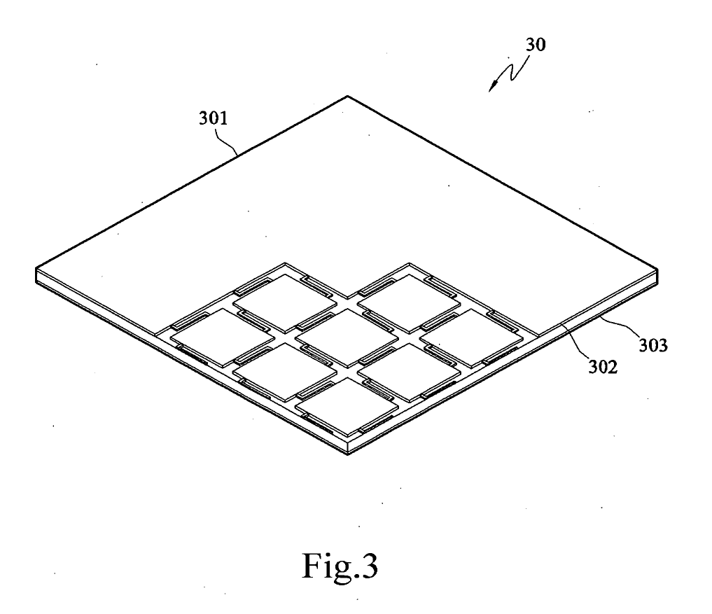

Please refer to FIG. 3 of a schematic view of the EBG structure according to the present invention. As shown in FIG. 3, the multilayer PCB 301 is formed by laminating a plurality of parallel lamination plates together, in which at least a lamination plate 3011 and a lamination plate 3012 is included. Referring to FIG. 1 again, a plurality of electronic components is disposed on the outer layer of the multilayer PCB 301 (not shown) and the outer layer of the multilayer PCB 101. The electronic components include integrated circuits and decoupling capacitors. The lamination plate 3011 and the lamination plate 3012 can be a pair of parallel plate, i.e., when one is the power layer, the other is the ground layer.

According to a preferred embodiment of the present invention, at least a first electronic component and a second electronic component (not shown) are disposed on the outer layer of the multilayer PCB 301. In order to achieve the electrical connection between the first and second electronic components and the lamination plate 3011, vias are formed penetrating through lamination plate 3011 from the outer layer. Through the vias, the respective pins of the first electronic component and the second electronic component can be electrically connected to the lamination plate 3011, and the electrical ports on the lamination plate 3011 are port 304 and port 305 respectively.

The technical scheme of the present invention includes using the EBG structure only on the linear transmission path from the port 304 to the port 305 on the lamination plate 3011. In the lamination plate 3011, the region of the linear path between the port 304 and the port 305 or the surrounding regions uses the EBG structure to constitute the first portion of the entire lamination plate 3011. The second portion in addition to the first portion is a plane without the EBG structure. Compared with the conventional art which completely uses the EBG structure on the power layer 2011, the present invention uses the EBG structure only in the partial region of the lamination plate 3011, thereby increasing the area of the lamination plate 3011.

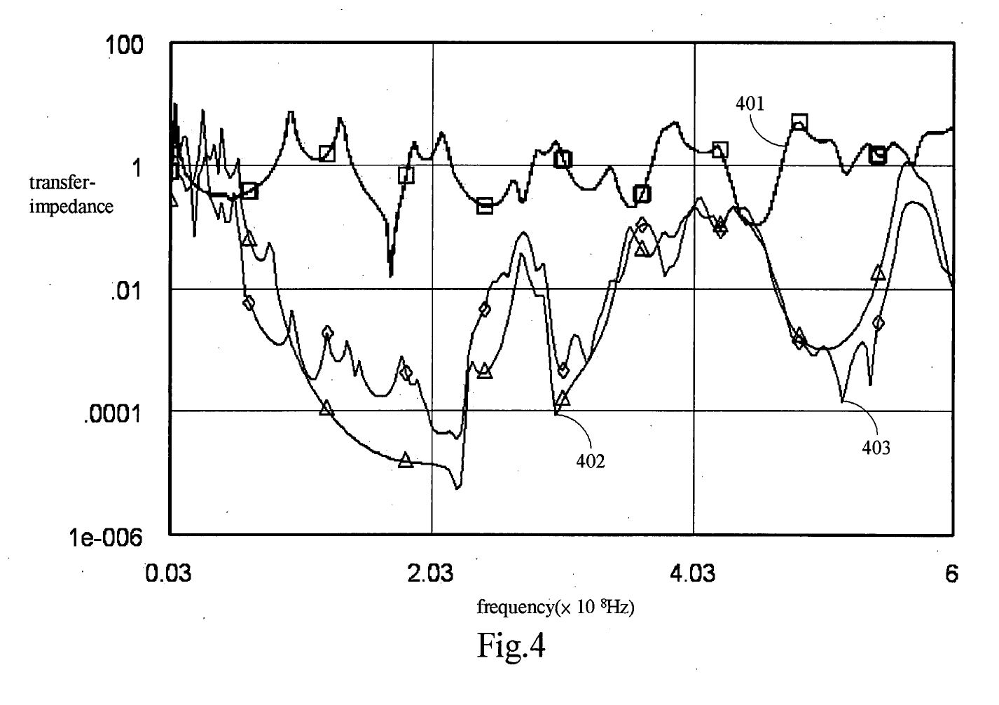

Please refer to FIG. 4 of a diagram of transfer-impedance curve after using the EBG structure plane according to the present invention. As shown in FIG. 4, when the frequency is more than 500 MHz, the transfer-impedance curve 403 not only using the EBG structure plane according to the present invention has a smaller transfer-impedance than that of the transfer-impedance curve 401 without using the EBG structure plane. And when the frequency is less than 5 GHz, the curve 403 has a smaller transfer-impedance than the transfer-impedance curve 402 using the EBG structure only.

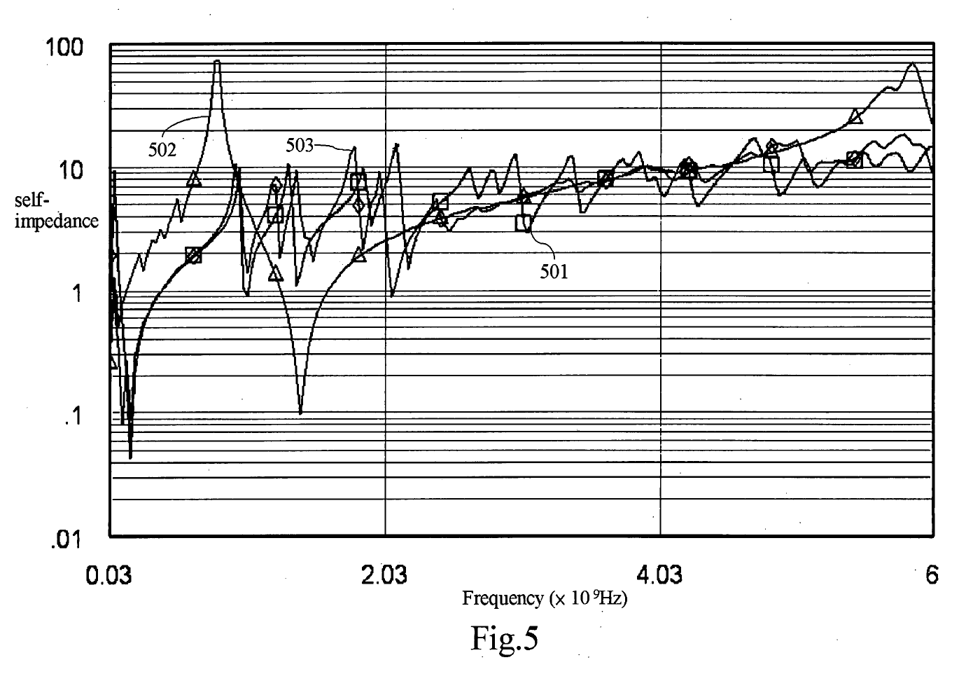

Please refer to FIG. 5 of a diagram of self-impedance curve after using the EBG structure plane according to the present invention. According to the figure, when the frequency is less than 2.03 GHz, the self-impedance curve 502 using the EBG structure plane only has a large variation of the self-impedance, and the self-impedance curve 503 not only using the EBG structure plane according to the present invention has a small variation of the impedance. And when the frequency is more than 2.03 GHz, the self-impedance curve 503 of the EBG structure plane according to the present invention has a stable self-impedance value compared with the self-impedance curve 501 without using the EBG structure plane and the self-impedance curve 502 using the EBG structure plane only.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A layout design of a multilayer printed circuit board (PCB), the multilayer PCB at least comprising a first lamination plate having at least a first electronic component and a second electronic component disposed thereon and a second lamination plate, the first electronic component and the second electronic component being electrically connected to a first port and a second port on the second lamination layer respectively, wherein:
the second lamination plate is formed with a partial electromagnetic band gap (EBG) structure region, and the partial EBG structure region comprises the region of a linear path between the first port and the second port.

2. The layout design of a multilayer PCB as claimed in claim 1, wherein the second lamination plate is a power layer.

3. The layout design of a multilayer PCB as claimed in claim 1, wherein the second lamination plate is a ground layer.

4. The layout design of a multilayer PCB as claimed in claim 2, wherein the first electronic component and the second electronic component are selected from among an integrated circuit (IC) and a decoupling capacitor.

5. The layout design of a multilayer PCB as claimed in claim 3, wherein the first electronic component and the second electronic component are selected from among an integrated circuit (IC) and a decoupling capacitor.

6. The layout design of a multilayer PCB as claimed in claim 4, wherein the decoupling capacitor is electrically connected to the integrated circuit and the second lamination plate respectively.

7. The layout design of a multilayer PCB as claimed in claim 5, wherein the decoupling capacitor is electrically connected to the integrated circuit and the second lamination plate respectively.
